(19) United States
(12) Patent Application Publication
(10) Pub. No.: US 2011/0292629 A1
(43) Pub. Date: Dec. 1, 2011

(54) RECEIVING APPARATUS

(75) Inventors: Minoru Kidena, Kobe-shi (JP); Shinichi Tanaka, Kobe-shi (JP)

(73) Assignee: FUJITSU TEN LIMITED, KOBE-SHI (JP)

(21) Appl. No.: 13/116,681

(22) Filed: May 26, 2011

(30) Foreign Application Priority Data
May 31, 2010 (JP) 2010-125247

(51) Int. Cl. H05K 1/11

(52) U.S. Cl. 361/803

(57) ABSTRACT

A receiving apparatus includes two electronic boards having flat surfaces that are disposed substantially-parallel to each other and that at least partially overlap each other, and an antenna that is mounted on the two electronic boards. The antenna includes a first metal line that is mounted along the flat surface of a first electronic board out of the two electronic boards, and a second metal line that is disposed substantially-perpendicular to the flat surfaces of the two electronic boards, a first end of the second metal line electrically connected to the first metal line and a second end of the second metal line electrically connected to a circuit on a second electronic board out of the two electronic boards. This enables the antenna to be integrated with the two electronic boards. As a result, it is possible to reduce the production cost while higher performance in receiving a radio wave is provided.

### BACKGROUND OF THE INVENTION

1. Field of the Invention

The invention relates to a receiving apparatus that receives a radio wave.

2. Description of the Background Art

Some of controllers implement various controls based on a radio wave received via an installed antenna. The antenna installed in such a controller is designed to offer higher reception performance.

In an example, a controller 11X as shown in FIG. 1 is upgraded in reception performance regarding a radio wave DP1 reaching a flat surface of an electronic board. This is because an antenna ATX designed in an L-shaped pattern is wired on the electronic board. Japanese Patent Laid-open Publication No. 2005-110123 discloses such a technology. However, regarding a radio wave DP2 reaching a side of the electronic board (i.e. a radio wave whose polarization is perpendicular to the electronic board), the controller 11X is degraded in reception performance of the antenna.

Thus, a controller 11Y as shown in FIG. 2, for example, adopts a technology for mounting on the electronic board a solid antenna ATY supported on a pedestal S to upgrade in reception performance regarding not only the radio wave DP1 reaching a flat surface of the electronic board but also the radio wave DP2 reaching a side of the electronic board.

However, adopting such a solid antenna in a controller causes a cost-up problem relating to material cost and production hours for producing a pedestal that supports the solid antenna.

### SUMMARY OF THE INVENTION

According to one aspect of the invention, a receiving apparatus that receives a radio wave includes two electronic boards having flat surfaces that are disposed substantially-parallel to each other and that at least partially overlap each other, and an antenna that is mounted on the two electronic boards and that receives the radio wave. The antenna has a first metal line that is mounted along the flat surface of a first electronic board out of the two electronic boards, and a second metal line that is disposed substantially-perpendicular to the flat surfaces of the two electronic boards, a first end of the second metal line electrically connected to the first metal line and a second end of the second metal line electrically connected to a circuit on a second electronic board out of the two electronic boards.

On the two electronic boards, the first metal line is mounted along the flat surface of the first electronic board out of the two electronic boards and the second metal line is disposed substantially-perpendicular to the flat surfaces of the two electronic boards. This enables the antenna having the first metal line and the second metal line to be integrated with the two electronic boards. As a result, the receiving apparatus can offer higher performance in receiving the radio wave, and production cost can be reduced.

According to another aspect of the invention, in the receiving apparatus, the second metal line has a part of a first connector that is disposed on the first electronic board, and a part of a second connector that connects to the part of the first connector and is disposed on the second electronic board.

The second metal line is made up of a part of the first connector disposed on the first electronic board and a part of the second connector disposed on the second electronic board. This enables a part of the antenna to be made up of the first connector and the second connector. As a result, production cost can be reduced.

According to another aspect of the invention, in the receiving apparatus, the first metal line is in a letter-L shape having a pair of mutually-perpendicular lines in plan view of the flat surface.

Since the first metal line is in the letter-L shape in plan view of the flat surface, the receiving apparatus can offer higher performance in receiving the radio wave reaching the flat surface of the first electronic board, and a part of the antenna can be integrated with the first electronic board. As a result, production cost can be reduced.

Therefore, the object of the invention is to provide a receiving apparatus including an antenna that offers higher reception performance and that can be produced at a lower cost.

These and other objects, features, aspects and advantages of the invention will become more apparent from the following detailed description of the invention when taken in conjunction with the accompanying drawings.

### BRIEF DESCRIPTION OF THE DRAWINGS

FIG. 1 shows an electronic board included in a controller.

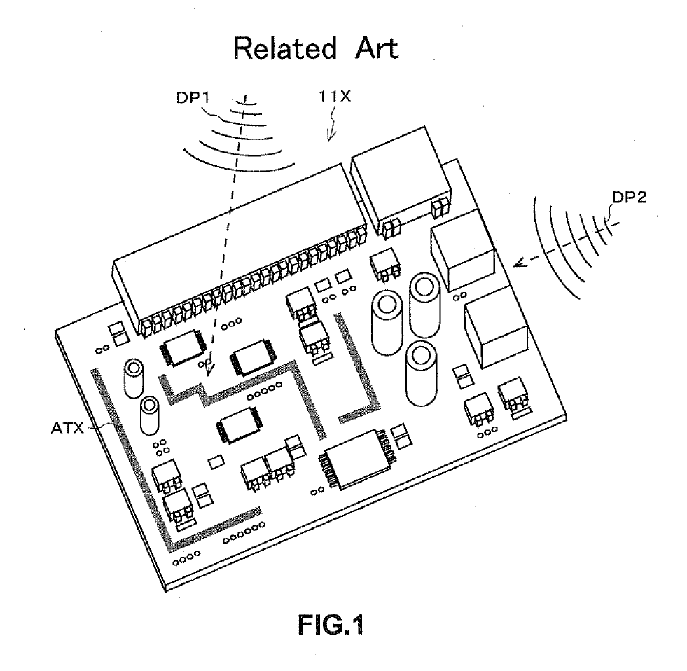

FIG. 2 shows another electronic board included in a controller.

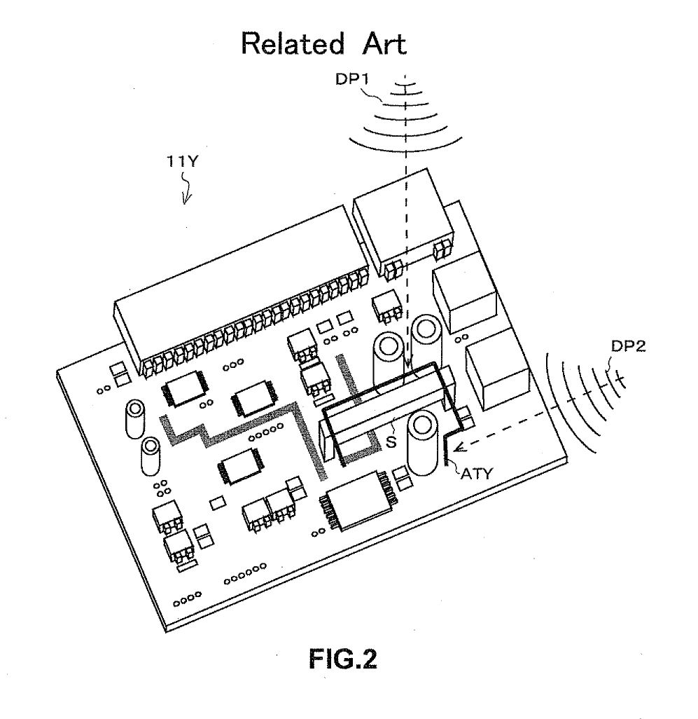

FIG. 3 shows a system configuration of the controller.

FIG. 4 shows the controller.

FIG. 5 shows an electronic board included in the controller.

FIG. 6 shows a sectional view of the electronic board included in the controller.

FIG. 7 shows a time chart of a control implemented by the controller.

### DESCRIPTION OF THE EMBODIMENTS

Hereafter, an embodiment of the invention is described with reference to attached figures. Three-dimensional orthogonal coordinate axes (X, Y, Z) included in the figures are used as needed for explanation of directions.

Although various apparatuses can adopt a controller relating to the invention, hereafter only the controller to be adopted in a vehicle is described. The controller may be deemed as a receiving apparatus because the controller includes an antenna that receives a radio wave.

<1. System Configuration of Controller>

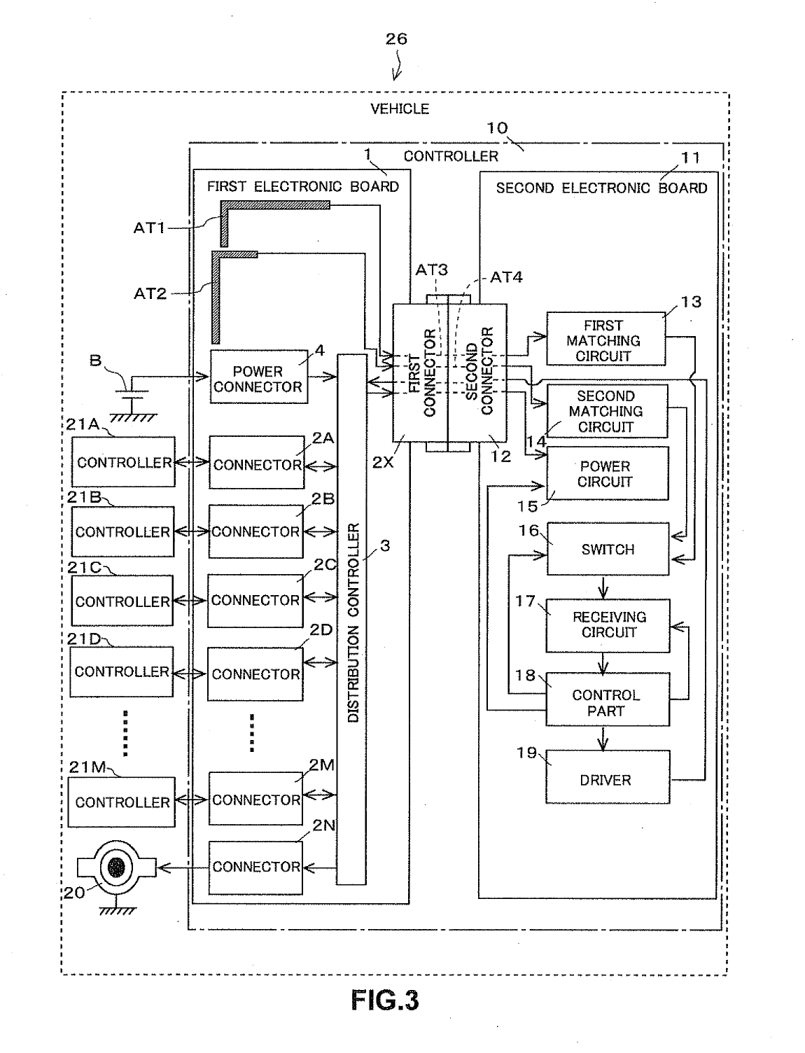

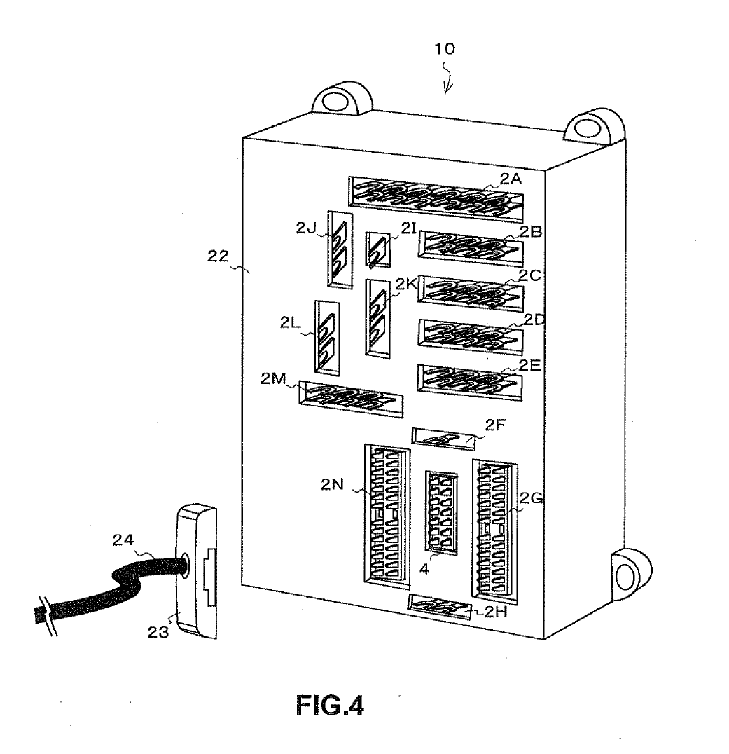

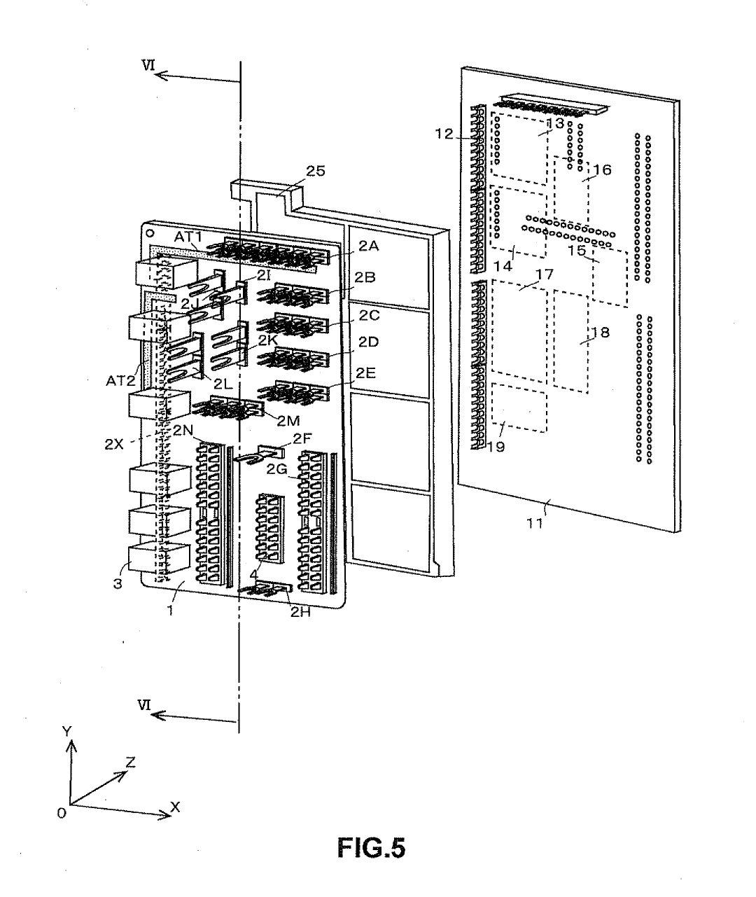

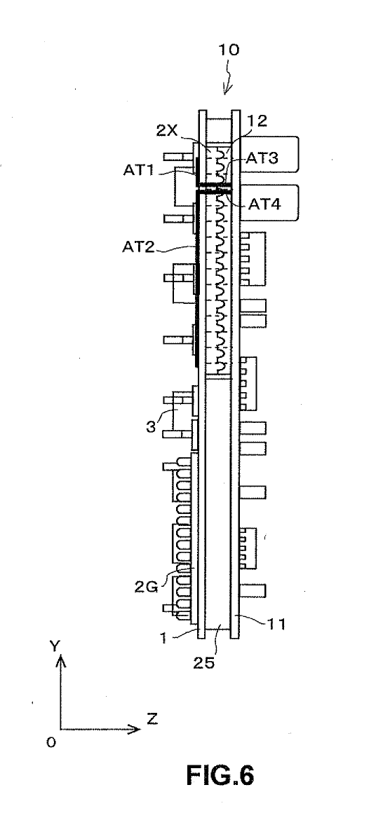

First, a configuration of the controller in the embodiment is described precisely with reference to FIG. 3, FIG. 4, FIG. 5 and FIG. 6. FIG. 3 shows a system configuration of a controller 10. As shown in FIG. 3, the controller 10 is included in a vehicle 26 and has a function of distributing electric power supplied by a battery B of a main power source of the vehicle 26, to other controllers from a controller 21A to a controller 21M and a motor 20 that are all external apparatuses. Hereafter, the function of distributing electric power is referred to as an electric power distribution function. Further, the controller 10 has a function of controlling the motor 20 that is an object to be controlled when receiving a radio wave indicating an instruction of unlocking or locking that is transmitted from the outside of the vehicle 26 by a remote control based on a user operation. The motor 20 is a door lock switching unit for toggling between locking and unlocking of a door of the vehicle 26. Hereafter, the function of controlling the motor 20 based on a radio wave transmitted by a remote control is referred to as a remote key operation function.

The controller 10, as shown in FIG. 4, includes a housing 22 from which protrude a plurality of connectors from a connector 2A to a connector 2N mounted on an electronic board included in the housing 22. A connector 23 assembled at one end of a harness 24 can be inserted into/extracted from the plurality of connectors from the connector 2A to the connector 2N. Further, the harness 24 includes another connector, not shown in FIG. 4, at the other end of the harness 24. Another connector at the other end of the harness 24 can be inserted into/extracted from other controllers from the controller 21A to the controller 21M and the motor 20. Thus, the controller 10 is connected to communicate with other controllers from the controller 21A to the controller 21M and the motor 20.

An internal configuration of the housing 22 of the controller 10 is described precisely based on FIG. 5. As shown in FIG. 5, the controller 10 includes two electronic boards, and a buffer 25 that is sandwiched between the two electronic boards. One of the two electronic boards (hereafter, referred to as “a first electronic board 1”) and the other of the two electronic boards (hereafter, referred to as “a second electronic board 11”) are disposed so that flat surfaces of both the first electronic board 1 and the second electronic board 11 are substantially-parallel to each other inside the housing 22. The flat surfaces of both the first electronic board 1 and the second electronic board 11 overlap with each other. Here, the first electronic board 1 and the second electronic board 11 may overlap at least partially, while it is not necessary to overlap them entirely.

A first connector 2X is disposed on the first electronic board 1, and a second connector 12 is disposed on the second electronic board 11. When the first electronic board 1 and the second electronic board 11 are superposed substantially in parallel to each other inside the housing 22, the first connector 2X and the second connector 12 are connected electrically.

The first electronic board 1 is used for the electric power distribution function. Thus, the first electronic board 1 needs to distribute electric power supplied by the battery B to other controllers from the controller 21A to the controller 21M. Further, the first electronic board 1 needs to implement data communication with other controllers from the controller 21A to the controller 21M.

The second electronic board 11 is used for the remote key operation function. Thus, the second electronic board 11 needs to obtain various data stored in other controllers from the controller 21A to the controller 21M, from those controllers from the controller 21A to the controller 21M.

Therefore, both the first electronic board 1 and the second electronic board 11 need to be connected to other controllers from the controller 21A to the controller 21M via harnesses and others. However, if each of the first electronic board 1 and the second electronic board 11 is connected to a plurality of harnesses, the area for installing other controllers from the controller 21A to the controller 21M in the vehicle 26 is jammed with the harnesses. This causes a problem in which the area for installing other controllers from the controller 21A to the controller 21M is constrained. This also causes another problem in which the extra cost to produce the harnesses to be adopted is incurred.

In the controller 10 of the embodiment, only the first electronic board 1 is connected to other controllers from the controller 21A to the controller 21M via the harnesses 24. The first connector 2X of the first electronic board 1 and the second connector 12 of the second electronic board 11 are connected electrically. This enables transmitting and receiving of signals between the first electronic board 1 and the second electronic board 11. Thus, first, the first electronic board 1 obtains various data from the other controllers from the controller 21A to the controller 21M via the harnesses 24, and then, the second electronic board 11 receives the various data via the first connector 2X and the second connector 12. This is the method to solve the problem mentioned above in the controller 10 of the embodiment.

<2. First Electronic Board>

Next, the first electronic board 1 included in the controller 10 is described precisely. The first electronic board 1 is a rectangular plate. The first electronic board 1 is also a metal core substrate made up of a metal plate coated by insulating resin. Since this metal core substrate includes a metal plate inside, the metal core substrate radiates locally-generated heat away to the air by dispersing the heat in the whole thermally-conductive metal plate. As a result, local temperature rise is prevented on the first electronic board 1.

On the first electronic board 1, the plurality of connectors from the connector 2A to the connector 2N, a distribution controller 3 (e.g. a relay), a power connector 4, two patterns of a pattern AT1 and a pattern AT2, and the first connector 2X are mounted.

The plurality of connectors from the connector 2A to the connector 2N are mounted on the flat surface (minus direction on Z-axis shown in FIG. 5 and FIG. 6) of the first electronic board 1. The plurality of connectors from the connector 2A to the connector 2N have a function of electrically connecting the controller 10 and the other controllers from the controller 21A to the controller 21M via harnesses.

The distribution controller 3 is mounted on the flat surface (minus direction on Z-axis shown in FIG. 5 and FIG. 6) of the first electronic board 1. The distribution controller 3 has a function of distributing the electric power inputted from the battery B to the plurality of connectors from the connector 2A to the connector 2N respectively. Heat is generated when this function distributes the electric power inputted from the battery B to the plurality of connectors from the connector 2A to the connector 2N respectively, and the heat is dispersed in the first electronic board 1 of the metal core substrate. This prevents electronic parts mounted in the area in which the heat is generated, from being damaged due to the generated heat.

The power connector 4 is mounted on the flat surface (minus direction on Z-axis shown in FIG. 5 and FIG. 6) of the first electronic board 1. The power connector 4 has a function of electrically connecting the first electronic board 1 and the battery B via the harness.

The two patterns of the pattern AT1 and the pattern AT2 are lines made with metal and are mounted along the flat surface (minus direction on Z-axis shown in FIG. 5 and FIG. 6) of the first electronic board 1. Each of the pattern AT1 and the pattern AT2 functions as a first metal line that is a part of a solid antenna described later.

Each of the pattern AT1 and the pattern AT2 is in a letter-L shape that has a pair of mutually-perpendicular lines in plan view of the first electronic board 1. As shown in FIG. 5, the pattern AT1 and the pattern AT2 are disposed so that the longer lines in the pairs of lines forming the pattern AT1 and the pattern AT2 run in different directions. Concretely, on the first electronic board 1, the longer line in the pair of lines forming one of the pattern AT1 and the pattern AT2 runs substantially-parallel to the shorter line in the pair of lines forming the other of the pattern AT1 and the pattern AT2.

The first connector 2X is mounted on the back of the flat surface (plus direction on Z-axis shown in FIG. 5 and FIG. 6) of the first electronic board 1. The first connector 2X is electrically connected to the second connector 12 mounted on the second electronic board 11. The first connector 2X includes a housing having an opening. The housing has a plurality of conductive connector pins in line.

FIG. 6 shows a sectional view in which the combination of the first electronic board 1 and the second electronic board 11 shown in FIG. 5 are cut at the VI-VI line running along the Y-axis as shown in FIG. 5. As shown in FIG. 6, the first connector 2X and the second connector 12 are electrically connected. In the state where the first connector 2X and the second connector 12 are connected, a part of the connector pins of the first connector 2X and a part of the connector pins of the second connector 12 are connected, and the connection forms a second metal line AT3 and a second metal line AT4 that are respective parts of the solid antennas described later. That is, each of the second metal line AT3 and the second metal line AT4 includes a part of the connector pins of the first connector 2X and a part of the connector pins of the second connector 12. As a result, the second metal line AT3 and the second metal line AT4 are disposed substantially-perpendicular to both the flat surfaces of the first electronic board 1 and the second electronic board 11 so as to connect the two of the first electronic board 1 and the second electronic board 11.

As shown in FIG. 6, the connector pin of the first connector 2X forming one line that is the second metal line AT3 connects to the pattern AT1 that is one of the first metal lines. The connector pin of the first connector 2X forming the other line that is the second metal line AT4 connects to the pattern AT2 that is the other of the first metal lines.

As above, one end (end on the side of the first electronic board 1) of each of the second metal line AT3 and the second metal line AT4 is electrically connected to each of the pattern AT1 and the pattern AT2 that are the first metal lines. The other end (end on the side of the second electronic board 11) of each of the second metal line AT3 and the second metal line AT4 is connected electrically to a circuit on the second electronic board 11. Here, the other ends of the pattern AT1 and the pattern AT2 not connected to the second metal lines are insulated.

As above, the connection between the one of the first metal lines and the one of the second metal lines forms one solid antenna. That is, one solid antenna includes one first metal line and one second metal line. Here, the first electronic board 1 and the second electronic board 11 are provided with two solid antennas. That is, one solid antenna includes the pattern AT1 and the second metal line AT3. The other solid antenna includes the pattern AT2 and the second metal line AT4.

As described above, the pattern AT1 and the pattern AT2 included in the two solid antennas are disposed so that the longer lines in the pairs of lines forming the pattern AT1 and the pattern AT2 run in different directions. Thus, these two solid antennas differ in receiving sensitivity depending on directions.

Since a plurality of solid antennas are modifications of a monopole antenna, the lengths are set based on a predetermined frequency of an object radio wave to be received. That is, the whole length of the solid antenna including the first metal line and the second metal line is set at the ¼ wavelength of the object radio wave.

As for both the first connector 2X and the second connector 12, a ground pin (GND pin) is disposed next to the connector pin forming the second metal line. A connector pin related to a communication function is disposed next to the ground pin (GND pin).

Next to the connector pin forming the second metal line, another type of connector pins, other than the connector pin related to the communication function, may be disposed. That is, only an alignment where the connector pin forming the second metal line is next to the connector pin related to the communication function is to be avoided. The alignments conforming to the above description can prevent the noises generated by electric signals passing through the connector pins related to the communication function from superimposing on the signals passing through the connector pin forming a part of the solid antenna.

<3. Second Electronic Boards

Next, the second electronic board 11 included in the controller 10 is described precisely. The second electronic board 11 is a rectangular plate. The second electronic board 11 is made up of insulating resin.

On the second electronic board 11, the second connector 12, a first matching circuit 13, a second matching circuit 14, a power circuit 15, a switch 16, a receiving circuit 17, a control part 18, and a driver 19 are mounted.

The second connector 12 is mounted on a back of a flat surface (minus direction on Z-axis shown in FIG. 5 and FIG. 6) of the second electronic board 11. The second connector 12 includes a housing having an opening. The housing has the plurality of conductive connector pins in line. In the state where the second connector 12 and the first connector 2X are connected, the plurality of the connector pins of the first connector 2X and the plurality of the connector pins of the second connector 12 are connected.

The first matching circuit 13 is formed on the flat surface (plus direction on Z-axis shown in FIG. 5 and FIG. 6) of the second electronic board 11. The first matching circuit 13 includes various electronic parts. The first matching circuit 13 is also electrically connected to the second metal line AT3 that is included in one of the two solid antennas. The first matching circuit 13 has a function of matching impedance (impedance matching) when outputting electric signals for the next process.

The second matching circuit 14 is formed on the flat surface (plus direction on Z-axis shown in FIG. 5 and FIG. 6) of the second electronic board 11. The second matching circuit 14 includes various electronic parts. The second matching circuit 14 is also electrically connected to the second metal line AT4 that is the other of the two solid antennas. The second matching circuit 14 has a function of matching impedance (impedance matching) when outputting electric signals for the next process.

The power circuit 15 is formed on the flat surface (plus direction on Z-axis shown in FIG. 5 and FIG. 6) of the second electronic board 11. The power circuit 15 includes various electronic parts. The power circuit 15 also has a function of providing power to other circuits. The timing of providing power is controlled by the control part 18.

The switch 16 is mounted on the flat surface (plus direction on Z-axis shown in FIG. 5 and FIG. 6) of the second electronic board 11. The switch 16 is, for example, a switching transistor. The switch 16 switches between the functions of transmitting an electric signal from the first matching circuit 13 to the receiving circuit 17 and transmitting an electric signal from the second matching circuit 14 to the receiving circuit 17. The control part 18 makes a selection between the two functions.

The receiving circuit 17 is formed on the flat surface (plus direction on Z-axis shown in FIG. 5 and FIG. 6) of the second electronic board 11. The receiving circuit 17 includes various electronic parts. The receiving circuit 17 has a function of generating an electric signal that the control part 18 can identify based on the received radio wave.

The control part 18 is mounted on the flat surface (plus direction on Z-axis shown in FIG. 5 and FIG. 6) of the second electronic board 11. The control part 18 includes various electronic parts such as CPU and ROM storing predetermined programs. The control part 18 has the remote key operation function cooperating with other elements.

The driver 19 is formed on the flat surface (plus direction on Z-axis shown in FIG. 5 and FIG. 6) of the second electronic board 11. The driver 19 includes various electronic parts. The driver 19 has a function of generating and outputting electric signals for controlling the motor 20 that is an object to be controlled.

<4. Buffer>

Next, the buffer 25 included in the controller 10 is described precisely. As shown in FIG. 6, the buffer 25 is sandwiched between the first electronic board 1 and the second electronic board 11. That is, the buffer 25 fills the space formed when the first connector 2X and the second connector 12 are connected to combine the first electronic board 1 and the second electronic board 11. When the connector 23 and the like are inserted in or extracted from the plurality of connectors from the connector 2A to the connector 2N mounted on the first electronic board 1, the buffer 25 also softens the force applied to the first electronic board 1 to prevent the force from reaching the second electronic board 11

As above, the controller 10 stores the combination of the first electronic board 1 and the second electronic board 11 in the housing 22, in which the first connector 2X included in the first electronic board 1 and the second connector 12 included in the second electronic board 11 are connected. In the controller 10, a part of the solid antenna is disposed in a controller sidepiece which was thickened due to structural requirement. That is, each of the second metal line AT3 and the second metal line AT4 that are parts of the solid antennas is disposed substantially-perpendicular to the first electronic board 1 and the second electronic board 11 so as to connect between the first electronic board 1 and the second electronic board 11. Thus, the controller 10 does not need a pedestal for supporting the solid antennas. As a result, the cost for producing pedestals is saved.

<5. Remote Key Operation Function>

Next, a remote key operation function implemented by the control part 18 included in the second electronic board 11 is described precisely.

The control part 18 provides electric power provided from the first electronic board 1 to the first matching circuit 13, the second matching circuit 14, etc. intermittently by controlling the power circuit 15. That is, the control part 18 makes respective circuits on or off intermittently (hereinafter, referred to as intermittent power control). The power circuit 15 also has a function of converting the voltage of electric power supplied from the first electronic board 1 to an appropriate voltage.

As above, the control part 18 included in the second electronic board 11 implements the intermittent power control for circuits. The reason is that the second electronic board 11 is used for the remote key operation function. The second electronic board 11 must be kept ready for receiving a radio wave indicating an instruction of unlocking or locking transmitted by a remote control based on a user operation. On the other hand, if those circuits are kept powered, the current consumption increases.

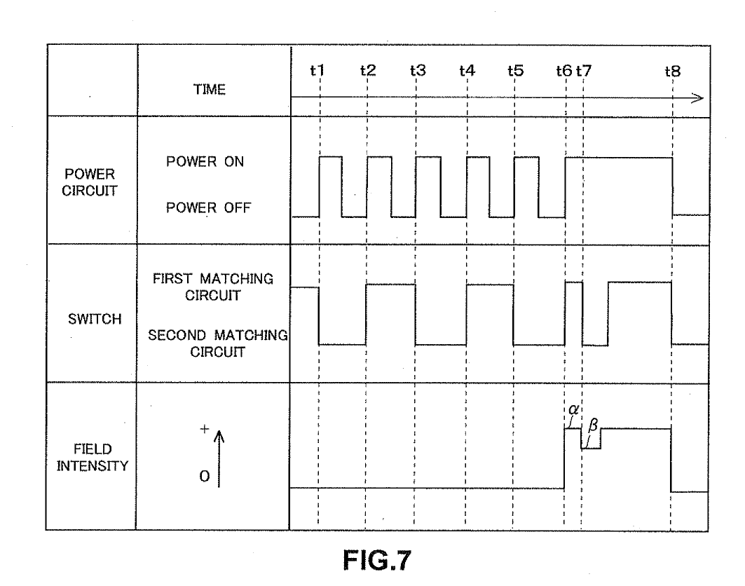

The intermittent power control is described concretely based on FIG. 7. The controller 10 constantly has supplied the power to the second electronic board 11 since the controller 10 was installed on the vehicle 26 and set by a user. The control part 18 included in the second electronic board 11 implements the intermittent power control described above between a timing t1 and a timing t6 shown in FIG. 7.

The control part 18 also supplies the power alternately to the first matching circuit 13 and the second matching circuit 14 by controlling the switch 16 at a predetermined timing. As a result, the first matching circuit 13 and the second matching circuit 14 work alternately. When one of the first matching circuit 13 and the second matching circuit 14 works, a solid antenna connected to the working circuit is ready for receiving a radio wave transmitted by a remote control.

That is, as shown in FIG. 7, the control part 18 selects the second matching circuit 14 by the switch 16 at the timing t1 of power-on timing to make the solid antenna connecting to the second matching circuit 14 ready for receiving a radio wave. Since the field intensity is zero at the timing t1, the control part 18 judges that the antenna receives no radio wave and continues the intermittent power control.

Next, the control part 18 selects the first matching circuit 13 by the switch 16 at the timing t2 of power-on timing to make the solid antenna connected to the first matching circuit 13 ready for receiving a radio wave. Since the field intensity is zero at the timing t2, the control part 18 judges that the solid antenna receives no radio wave and continues the intermittent power control. As above, the control part 18 implements intermittently a control for monitoring whether or not the radio wave is received.

The control part 18 selects the first matching circuit 13 by the switch 16 at the timing t6. Since the solid antenna connected to the first matching circuit 13 detects a field intensity α that is above the prescribed level when the control part 18 makes the solid antenna ready for receiving a radio wave, the control part 18 stops the intermittent power control and implements a control so as to keep the power on.

The control part 18 selects the second matching circuit 14 by the switch 16 at a timing t7. Since the solid antenna connected to the second matching circuit 14 detects a field intensity β that is above the prescribed level when the control part 18 makes the solid antenna ready for receiving a radio wave, the control part 18 compares the values between the field intensity α and the field intensity β to identify a stronger field intensity.

In response to the comparison result, the control part 18 fixes the switch 16 to the first matching circuit 13 connected to the solid antenna which receives stronger field intensity. That is, as shown in FIG. 7, since the field intensity α is stronger than the field intensity β, the control part 18 fixes the switch 16 to select the first matching circuit 13 connected to the solid antenna which receives a radio wave of the field intensity α.

The control part 18 controls the motor 20 via the driver 19 based on a signal from the solid antenna that receives a radio wave having stronger field intensity. That is, in the case where the signal from the solid antenna indicates an instruction to unlock a door of the vehicle 26, the control part 18 controls the motor 20 to unlock the door. In the case where the signal from the solid antenna indicates an instruction to lock the door of the vehicle 26, the control part 18 controls the motor 20 to lock the door. In such a case, the control part 18 accepts or prohibits the control based on the signal received from other controllers from the controller 21A to the controller 21M. In an example, in the case where a signal received from an authentication unit that is one of the other controllers indicates authentication success, the control part permits the control. On the other hands, in the case where the signal received from the authentication unit that is one of the other controllers indicates authentication failure, the control part 18 prohibits the control. As above, the control part 18 fulfills the remote key operation function.

As above, the control part 18 controls the motor 20 based on the signal from the solid antenna receiving the radio wave having stronger field intensity out of the two solid antennas. Thus, even in the case where the controller 10 is installed on a different type of a vehicle and the installed position differs, or where positional relation between the controller 10 and another apparatus are different, the controller 10 can use a signal from the solid antenna having better receiving sensitivity out of the two solid antennas. As a result, the controller 10 can implement the control appropriately. Further, even in the case where a radio wave is transmitted from a different direction, the controller 10 can use a signal from the antenna that has better receiving sensitivity among a plurality of antennas. As a result, the controller 10 implements the control appropriately.

<6. Modification>

So far, the embodiment of the invention was described. However, the invention is not to be considered limited to the described embodiment above, but includes various modifications. This section describes other embodiments.

In the above embodiment, it was described that the second metal line includes a part of the first connector 2X and a part of the second connector 12. However, a second metal line is not limited to such a structure. In an example, a part of a structure that has conductivity and is disposed substantially-perpendicular to the board surfaces of two electronic boards, a first electronic board 1 and a second electronic board 11, may be used as a second metal line. Concretely, a screw, a screw hole formed by use of metal, etc. for fixing to combine the two electronic boards may be used as the second metal line.

It was described that the second electronic board 11 of the above embodiment is used for the remote key operation function. In this regard, any function having a remote control function may be used. For example, a function having the remote engine starting that implements a control of starting an engine based on a radio wave indicating a user instruction of engine starting may be used.

While the invention has been shown and described in detail, the foregoing description is in all aspects illustrative and not restrictive. It is therefore understood that numerous other modifications and variations can be devised without departing from the scope of the invention.

What is claimed is:

1. A receiving apparatus that receives a radio wave, the receiving apparatus comprising:
two electronic boards having flat surfaces that are disposed substantially-parallel to each other and that at least partially overlap each other; and
an antenna that is mounted on the two electronic boards and receives the radio wave, wherein
the antenna includes:
a first metal line that is mounted along the flat surface of a first electronic board out of the two electronic boards, and
a second metal line that is disposed substantially-perpendicular to the flat surfaces of the two electronic boards, a first end of the second metal line electrically connected to the first metal line and a second end of the second metal line electrically connected to a circuit on a second electronic board out of the two electronic boards.

2. The receiving apparatus of claim 1, wherein
the second metal line includes:
a part of a first connector that is disposed on the first electronic board, and
a part of a second connector that connects to the part of the first connector and is disposed on the second electronic board.

3. The receiving apparatus of claim 1, wherein
the first metal line is in a letter-L shape including a pair of mutually-perpendicular lines in plan view of the flat surface.

4. The receiving apparatus of claim 3, wherein
the two electronic boards include a plurality of the antennas, and
the first metal lines of the plurality of antennas are disposed so that directions of longer lines in the pairs of mutually-perpendicular lines are different from one another.

5. The receiving apparatus of claim 1, wherein
a length of the antenna is set based on a frequency of the radio wave to be received.

6. A control apparatus that controls an object-to-be-controlled, the control apparatus comprising:
two electronic boards having flat surfaces that are disposed substantially-parallel to each other and that at least partially overlap each other;
an antenna that is disposed on the two electronic boards and that receives a radio wave; and
a controller that controls the object-to-be-controlled based on a signal from the antenna receiving the radio wave, wherein
the antenna includes:
a first metal line mounted along the flat surface of a first electronic board out of the two electronic boards, and
a second metal line that is disposed substantially perpendicular to the flat surfaces of the two electronic boards, a first end of the second metal line electrically connected to the first metal line and a second end of the second metal line electrically connected to a circuit on a second electronic board out of the two electronic boards.

7. The control apparatus of claim 6, wherein
the controller is mounted on the second electronic board and connects electrically to the circuit on the second electronic board.

8. The control apparatus of claim 6, wherein
the two electronic boards include a plurality of the antennas,
each of the first metal lines of the plurality of antennas is in a letter-L shape having a pair of mutually-perpendicular lines,
the first metal lines of the plurality of antennas are disposed so that directions of longer lines in the pairs of mutually-perpendicular lines are different from one another, and
the controller controls the object-to-be-controlled based on a signal from the antenna receiving the radio wave having a largest field intensity among the plurality of antennas.

9. The control apparatus of claim 6, further comprising:
a distribution unit that is mounted on the first electronic board and distributes electric power to an external apparatus, wherein
the first electronic board is a metal core substrate.

10. The control apparatus of claim 7, further comprising:
a communication unit that is mounted on the first electronic board and receives an electric signal from an external apparatus; and
a connector to send and receive the electric signal between the first electronic board and the second electronic board, wherein
the controller controls the object-to-be-controlled based on the electric signal.
